(19) United States
(12) Patent Application Publication
(10) Pub. No.: US 2005/0248029 A1
(43) Pub. Date: Nov. 10, 2005

(54) Embedded chip semiconductor without wire bondings

(76) Inventor: Roger Chang, Taoyuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/841,499

(22) Filed: May 10, 2004

(51) Int. Cl. H01L 23/48

(52) U.S. Cl. 257/734

(57) ABSTRACT

An embedded chip semiconductor has a substrate, at least one chip, an insulation boundary and a circuit pattern. The substrate has a thickness, a top surface, a bottom surface and at least one chip recess. The at least one chip has a thickness, a top face, a bottom face, outer edges and multiple terminals and is mounted in a corresponding chip recess. The thickness of the chip is equal to or less than the thickness of the substrate. The insulation boundary is formed in the chip recess around the edges of the chip. The circuit pattern is formed on the bottom surface of the nonmetallic substrate and connected to the multiple terminals of the chip. Therefore, a printed circuit board making process is employed to mass-produce the semiconductors. Further, the chip connected to the circuit pattern does not the wire bondings so the semiconductor fabrication process has good yield.

### BACKGROUND OF THE INVENTION

1. Field of the Invention

The present invention relates to a semiconductor package and more particularly to an embedded chip semiconductor without wire bondings.

2. Description of Related Art

With reference to FIG. 6, a conventional semiconductor package (50) comprises a leadframe (500), a chip (60), molded encapsulant (80) and wire bondings (70). The leadframe has a die pad (52) and multiple leads (51) around the die pad (52). A general process to package the semiconductor package (50) includes the following steps:

(a) mounting the chip (60) on the die pad (52) of the leadframe (500);

(b) connecting the chip (60) to the leads (51) of the leadframe (500) by the wire bondings (70); and

(c) encapsulating the chip (60), wire bondings (70) and portions of the leadframe (500) with molded encapsulant (80) to complete a single semiconductor product.

For mass production of the semiconductor package (50), steps (a), (b) and (c) are executed repeatedly. Therefore, the production rate of the semiconductor packages is limited by the conventional production process. Furthermore, step (b) employs very narrow gauge gold wire to bond the chip and the leads so the molded encapsulant can break the wire bondings. Thus, the wire bonding connecting the chip and the leads should be improved to increase the yield of the production process of the semiconductor packages. Furthermore, the necessity of mounting the chip on the die pad and connecting the chip to the leads with the wire bondings makes reducing the thickness of the semiconductor package very difficult.

To overcome the shortcomings, the present invention provides an embedded chip semiconductor package without wire bonding to mitigate or obviate the aforementioned problems.

### SUMMARY OF THE INVENTION

The main objective of the invention is to provide an embedded chip semiconductor package fabricated with a printed circuit board fabrication process to effectively increase the mass production yield and decrease the total thickness of the semiconductor package.

In the printed circuit board fabrication process, a board with multiple integrated substrates is fabricated to accommodate multiple embedded chip semiconductors. At least one chip recess is defined in each substrate to hold a is chip in each recess. Insulation material is pressed into all the chip recesses to hold the chips in the chip recesses. At least one circuit pattern is formed on one side of each substrate. Multiple conductive vias are formed through the insulation material and connect corresponding terminals of each chip and the circuit pattern. The circuit pattern could be used as the leads of the semiconductor or could have solder bumps as the leads of the semiconductor.

Other objectives, advantages and novel features of the invention will become more apparent from the following detailed description when taken in conjunction with the accompanying drawings.

### BRIEF DESCRIPTION OF THE DRAWINGS

FIG. 1 is a side view in partial section of a first embodiment of an embedded chip semiconductor in accordance with the present invention;

FIG. 2 is a side view in partial section of a second embodiment of an embedded chip semiconductor in accordance with the present invention;

FIG. 3 is a side view in partial section of a third embodiment of an embedded chip semiconductor in accordance with the present invention;

FIG. 4 is a side view in partial section of a fourth embodiment of an embedded chip semiconductor in accordance with the present invention;

FIGS. 5A to 5J are side plan views in partial section of interim products of the second embodiment of the embedded chip semiconductor in FIG. 2 produced with a printed circuit board process; and

FIG. 6 is a side view in partial section of a conventional semiconductor package in accordance with the prior art.

### DETAILED DESCRIPTION OF THE PREFERRED EMBODIMENT

An embedded chip semiconductor in accordance with the present invention is fabricated with a printed circuit board fabrication process so the embedded chip semiconductor does not have wire bondings, and the single embedded chip semiconductors can be mass-produced.

With reference to FIG. 1, an embedded chip semiconductor in accordance with the present invention includes a substrate (10), at least one chip (12), an insulation boundary (13) and a circuit pattern (14).

The substrate (10) has a thickness (not numbered), a top surface (101), a bottom surface (102) and at least one chip recess (11). In the first embodiment, the substrate (10) is nonmetallic.

The at least one chip (12) has a thickness (not numbered), a top face (121), a bottom face (122), outer edges (not numbered) and multiple terminals (123). The thickness of the chip (12) is equal to or less than the thickness of the substrate (10). The top face (121) of the chip (12) is flush with the top surface (101) of the substrate (10) to form a coplanar face (not numbered). The terminals (123) are formed on the bottom face (122).

The circuit pattern (14) is formed on the bottom surface (102) of the substrate (10) and has an inner area (not numbered) and an outer area (not numbered), and the terminals (123) on the chip (12) are connected to the inner surface of the circuit pattern (14). The inner area of the circuit pattern (14) corresponds to the chip recess (11), the outer area is outside the inner area. The circuit pattern (14) is made of copper.

The insulation boundary (13) is formed in the chip recess (11) around the edges of the chip (12) to insulate the chip (12) from the substrate (10).

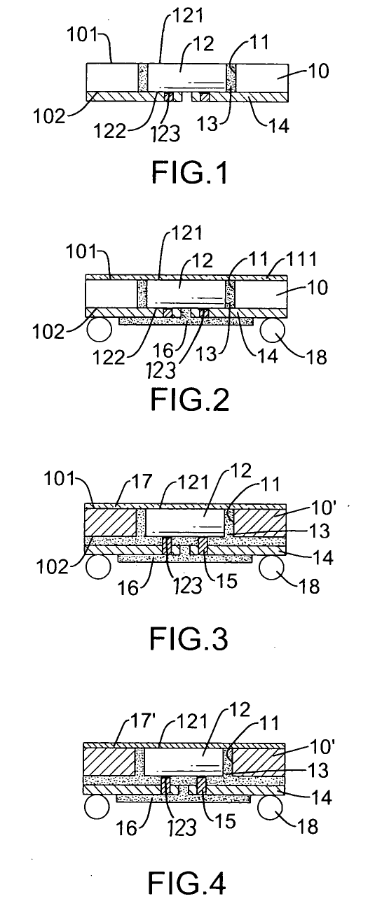

With reference to FIG. 2, a second embodiment of the embedded chip semiconductor in accordance with the present invention is similar the first embodiment, but the embedded chip semiconductor is packaged as a BGA type semiconductor. The second embodiment further comprises separation paint (16), multiple solder bumps (18) and an optional cover (17).

The inner area of the circuit pattern (14) is painted with separation paint (16), and the outer area of the circuit pattern (14) is exposed in the air. The solder bumps (18) are connected to the outer area of the circuit pattern (14). The optional cover (17) is formed on the coplanar face to protect the chip (12). If the chip (12) is a light emitting device or a light detector, the cover (17) is transparent.

With reference to FIG. 3, a third embodiment of the embedded chip semiconductor in accordance with the present invention is similar to the first embodiment, but the substrate (10′) is metallic, the insulation boundary (13) is expanded, and the embedded chip semiconductor further comprises multiple conductive vias (15). The insulation boundary (13) is further formed between the bottom surface (102) of the substrate (10′) and the circuit pattern (14) to separate the metallic substrate (10′) from the circuit pattern (14). To connect the terminals (123) on the chip (12) to the circuit pattern (14), multiple conductive vias (15) corresponding to the terminals (123) are formed through the circuit pattern (14) and the insulation material layer (13).

With further reference to FIG. 4, the cover (17′) may be a heat sink if the chip (12) is a general functional integrated circuit.

The chips (12) connected to the circuit patterns (14) in the embodiments of the present invention do not use wire bondings so a printed circuit board making process is used to mass-produce the embedded chip semiconductors.

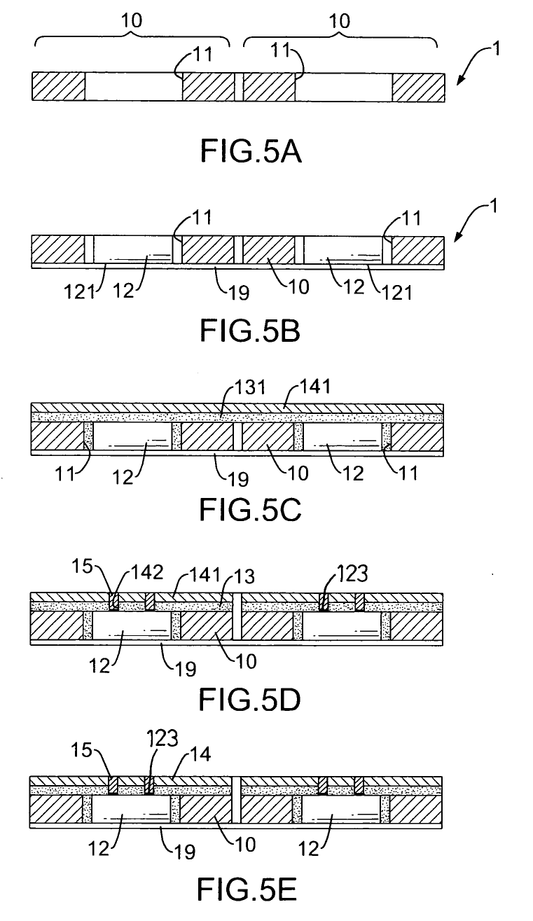

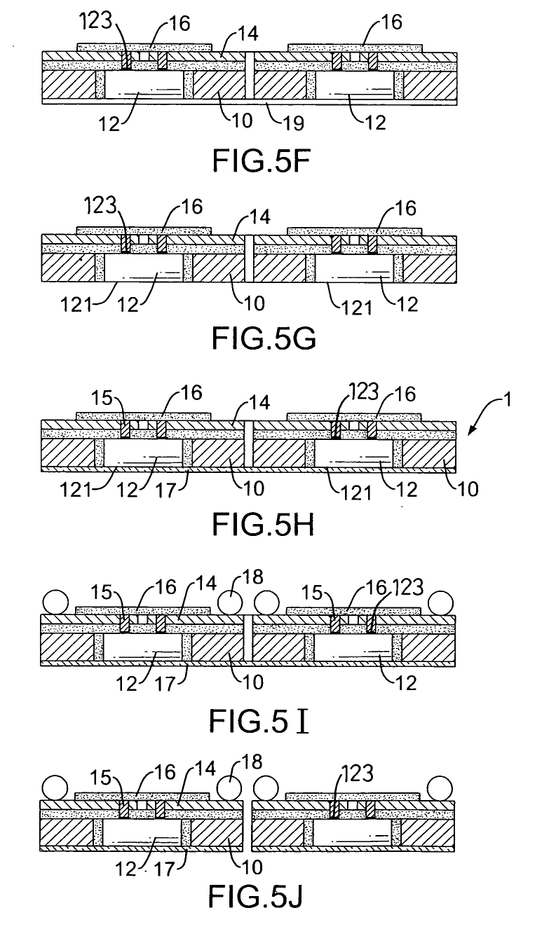

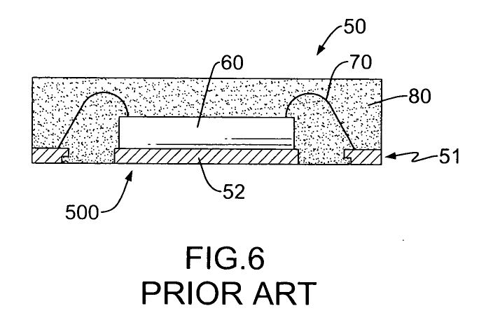

With reference to FIGS. 5A to 5J, the embedded chip semiconductor is fabricated essentially from top to bottom, and the process includes the following steps.

(a) Preparing a board (1) having two sides and multiple substrates (10). At least one chip recess (11) is defined in each substrate (10) by an etching process or hole drilling process.

(b) Attaching a transfer film (19) to one side of the board (1);

(c) Mounting a chip (12) in each chip recess (11). The chip (12) is supported by the transfer film (19);

(d) Heat vacuum pressing insulation material (131) and a cooper sheet (141) onto the side of the board (1) opposite to the transfer film (19). The insulation boundary (13) also fills the chip recesses (11) around the chips (12), and the cooper sheet (141) is bonded to the insulation material (131).

(e) Drilling holes (142) through the cooper sheet (141) and the insulation material (131) until the terminals (123) of the chip (12) are exposed.

(f) Electroplating the holes (142) to form the conductive vias (15) and electrically connect the chip (12) to the cooper sheet (141).

(g) Transforming the cooper sheet (141) to the circuit pattern (14) by a pattern transfer process.

(h) Painting the inner area of the circuit pattern (14) with separation paint (16) and leaving the outer area exposed to the air.

(i) Removing the transfer film (19) to expose the coplanar face of the chip (12);

(j) Mounting cover (17) on the coplanar face of the board (1).

(k) Attaching the solder bumps (18) to the circuit pattern (14).

(l) Separating the substrates (10) from the board (1) to produce multiple single embedded chip semiconductors.

Step (b) could be incorporated into step (a) so the transfer film (19) is attached to the board (1) before defining the chip recesses (11). The structure of the embedded chip semiconductor as described allows the embedded chip semiconductors to be mass-produced with a high-yield printed circuit board fabrication process. The chip (12) and the circuit pattern (14) are connected by conductive vias (15) that are formed after forming the insulation boundary (13) so the connection between the chip (12) and the circuit pattern (10) is not broken when forming the insulation boundary (13). The thickness of the semiconductor package is significantly reduced because the chip is embedded in the substrate.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. An embedded chip semiconductor without wire bonding, comprising:
a substrate having a top surface, a bottom surface and at least one chip recess;
at least one chip mounted respectively in the at least one chip recess and having outer edges, a top face flush with the top surface of the substrate to form a coplanar face, a bottom face and multiple terminals formed on the bottom face;
a circuit pattern formed on the bottom surface of the substrate and having an inner area corresponding to the at least one chip recess and an outer area outside the inner area, and the terminals on the at least one chip connected to the circuit pattern; and
an insulation boundary formed in the at least one chip recess around the edges of the at least one chip to insulate the chip from the substrate.

2. The semiconductor as claimed in claim 1, further comprising a cover mounted on the coplanar face.

3. The semiconductor as claimed in claim 2, wherein the substrate is metallic and the insulation boundary is further formed between the bottom surface of the substrate and the circuit pattern.

4. The semiconductor as claimed in claim 3, wherein the terminals of the chip are connected to the circuit pattern by multiple conductive vias, each of which is formed through the circuit pattern and the insulation boundary to connect the terminals on the chip to the circuit pattern.

5. The semiconductor as claimed in claim 1, wherein the semiconductor further comprises multiple solder bumps attached to the outer area of the circuit pattern.

6. The semiconductor as claimed in claim 2, wherein the semiconductor further comprises multiple solder bumps attached to the outer area of the circuit pattern.

7. The semiconductor as claimed in claim 3, wherein the semiconductor further comprises multiple solder bumps attached to the outer area of the circuit pattern.

8. The semiconductor as claimed in claim 4, wherein the semiconductor further comprises multiple solder bumps attached to the outer area of the circuit pattern.

9. The semiconductor as claimed in claim 5, wherein the inner area of the circuit pattern is painted with separation paint.

10. The semiconductor as claimed in claim 6, wherein the inner area of the circuit pattern is painted with separation paint.

11. The semiconductor as claimed in claim 7, wherein the inner area of the circuit pattern is painted with separation paint.

12. The semiconductor as claimed in claim 8, wherein the inner area of the circuit pattern is painted with separation paint.

13. The semiconductor as claimed in claim 2, wherein the cover is transparent.

14. The semiconductor as claimed in claim 2, wherein the cover is a heat sink.
